(19) United States
(12) Patent Application Publication
(10) Pub. No.: US 2011/0227022 A1
(43) Pub. Date: Sep. 22, 2011

(54) Memristor Having a Nanostructure Forming An Active Region

(76) Inventor: Hans S. Cho, Palo Alto, CA (US)

(21) Appl. No.: 13/130,829

(22) PCT Filed: Jan. 15, 2009
(86) PCT No.: PCT/US2009/031158

§ 371 Date: May 24, 2011

(51) Int. Cl. H01L 45/00; H01L 21/62

(52) U.S. Cl. 257/3; 438/382; 257/E45.002; 257/E21.52

(57) ABSTRACT

A memristor having an active region having a first electrode, a second electrode, and a nanostructure connecting the first electrode with the second electrode. The nanostructure includes a generally insulating material configured to have an electrically conductive channel formed in the material. The nanostructure forms the active region and has a length and a thickness, where the length is substantially equivalent to a distance extending from the first electrode to the second electrode along the nanostructure and the thickness is a distance across the nanostructure substantially perpendicular to the length of the nanostructure. The length of the nanostructure is substantially greater than the thickness of the nanostructure.

### CROSS-REFERENCE TO RELATED APPLICATIONS

The present application has the same Assignee and shares some common subject matter with U.S. Patent Application Publication No. 20080090337 (Attorney Docket No. 200602631-1), filed on Oct. 3, 2006, by R. Stanley Williams, and U.S. patent application Ser. No. 12/243,853 (Attorney Docket No. 200703279-1), filed on Oct. 1, 2008, by Nate Quitoriano et al., the disclosures of which are hereby incorporated by reference in their entireties.

### BACKGROUND

Solid state memristive devices rely on the drift of mobile charge dopants upon the application of an electrical field, as discussed in the 20080090337 Patent Publication. These types of devices have been found to have promising properties in the fields of both digital and analog non-volatile electronic logic. To illustrate the increase potential of analog non-volatile electronic logic, synaptic computing has emerged as a potential technology that is enabled by the relatively small size, low cost, and low power consumption provided by solid state memristive devices.

Researchers have designed nano-scale reversible switches with an ON-to-OFF conductance ratio of 10⁴. Crossbar circuitry is often constructed using these types of switches. A useful configuration of this crossbar circuitry is a latch, which is an important component for constructing circuits and communicating between logic and memory. Researchers have described logic families entirely constructed from crossbar arrays of switches, as well as hybrid structures using switches and transistors. The application of such components to CMOS circuits has been found to increase the computing efficiency and performance of CMOS circuits. The devices that are presently fabricated have room for improvement particularly in terms of cyclability.

### BRIEF DESCRIPTION OF THE DRAWINGS

Embodiments are illustrated by way of example and not limited in the following figure(s), in which like numerals indicate like elements, in which:

FIG. 1A illustrates perspective view of a portion of a memristor, according to an embodiment of the invention;

FIG. 1B illustrates an enlarged, cross-sectional front view of the memristor depicted in FIG. 1A, according to an embodiment of the invention;

FIG. 10 illustrates a crossbar array employing a plurality of the memristors depicted in FIG. 1A, according to an embodiment of the invention;

FIG. 2 illustrates a side, cross-sectional view of a portion of a crossbar array, according to an embodiment of the invention and

FIG. 3 illustrates a flow diagram of a method of fabricating a memristor having an active region formed of a nanostructure, according to an embodiment of the invention.

### DETAILED DESCRIPTION

For simplicity and illustrative purposes, the principles of the embodiments are described by referring mainly to examples thereof. In the following description, numerous specific details are set forth in order to provide a thorough understanding of the embodiments. It will be apparent however, to one of ordinary skill in the art, that the embodiments may be practiced without limitation to these specific details. In other instances, well known methods and structures are not described in detail so as not to unnecessarily obscure the description of the embodiments.

Disclosed herein is a memristor composed of electrodes connected by a nanostructure, which comprises a switching material. The switching material forming the nanostructure is similar to the switching material, such as, transition metal oxides, in planar film switch structures. The nanostructure of the memristor disclosed herein, however, causes the active region of the memristor to have a nanometer-scale point contact region with the electrodes due to its nano-scale size. One result of this relatively small contact region is that the location of the active region may more easily and reliably be identified as compared with conventional memristor structures. In addition, the degree of certainty in the threshold voltage required to change the conductivity state of the active region may be relatively higher than in conventional memristor structures.

The term “self-assembled” as used herein refers to a system that naturally adopts some geometric pattern because of the identity of the components of the system; the system achieves at least a local minimum in its energy by adopting this configuration.

The term “singly configurable” means that a memristor is able to change its state only once via an irreversible process such as an oxidation or reduction reaction; such a memristor may be the basis of a programmable read only memory (PROM), for example.

The term “reconfigurable” means that a memristor can change its state multiple times via a reversible process such as an oxidation or reduction; in other words, the memristor may be opened and closed multiple times such as the memory bits in a random access memory (RAM).

The term “configurable” means either “singly configurable” or “reconfigurable”.

Micron-scale dimensions refer to dimensions that range from 1 micrometer to a few micrometers in size.

For the purposes of this application, nanometer scale dimensions refer to dimensions ranging from 1 to 50 nanometers. In addition, nanostructures have nano-scale dimensions and comprise wires, rod or ribbon-shaped conductors or semiconductors with widths or diameters having nanoscale dimensions.

A memristor is a two-terminal dynamical electrical device that acts as a passive current limiter in which the instantaneous resistance state is a function of bias history. One embodiment of a memristor is a two-terminal device in which the electrical flux, or time intergral of the electric field, between the terminals is a function only of the amount of electric charge, or time intergral of the current, that has passed through the device.

A crossbar is an array of switches, here memristors, that can connect each electrode in one set of approximately parallel electrodes to every member of a second set of approximately parallel electrodes that intersects the first set (usually the two sets of electrodes are approximately perpendicular to each other, but this is not a necessary condition).

As used herein, the functional dimension of the memristor is measured in nanometers (typically less than 50 nm), but the lateral dimensions may be nanometers or microns.

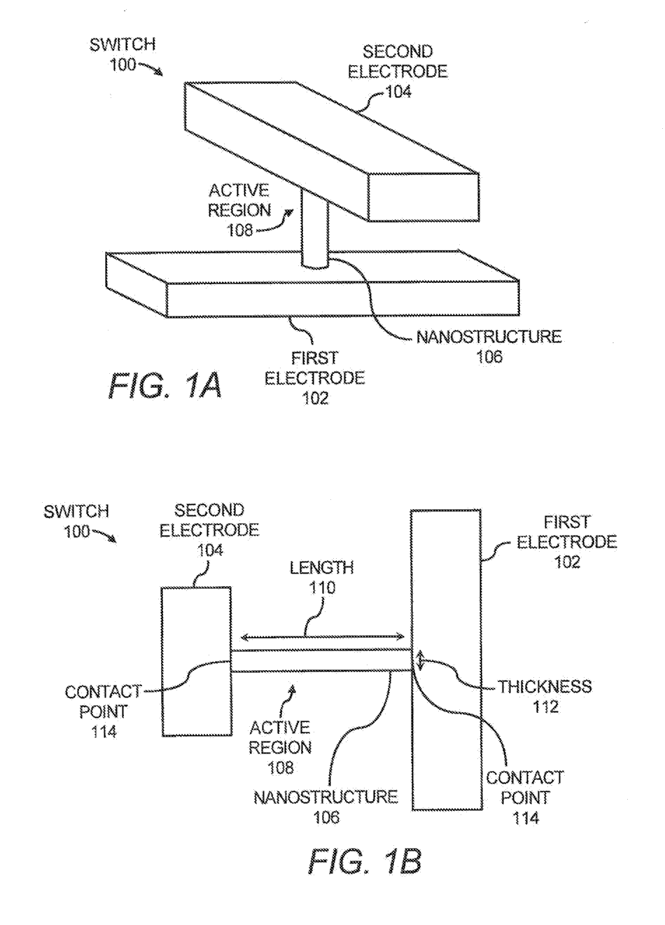

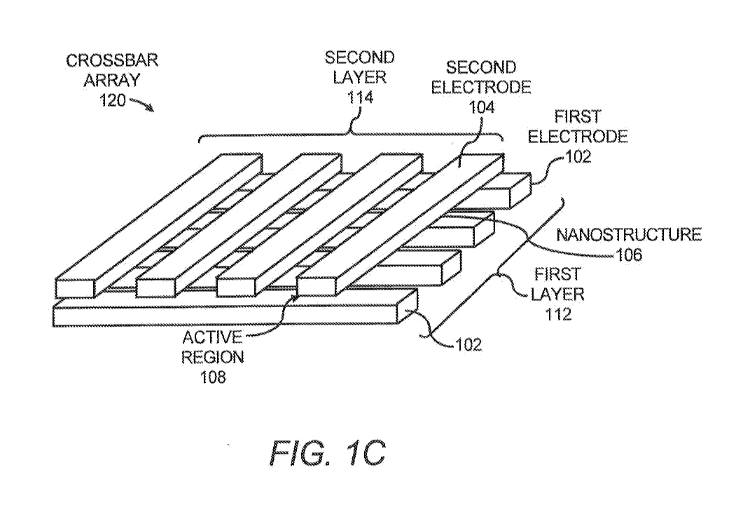

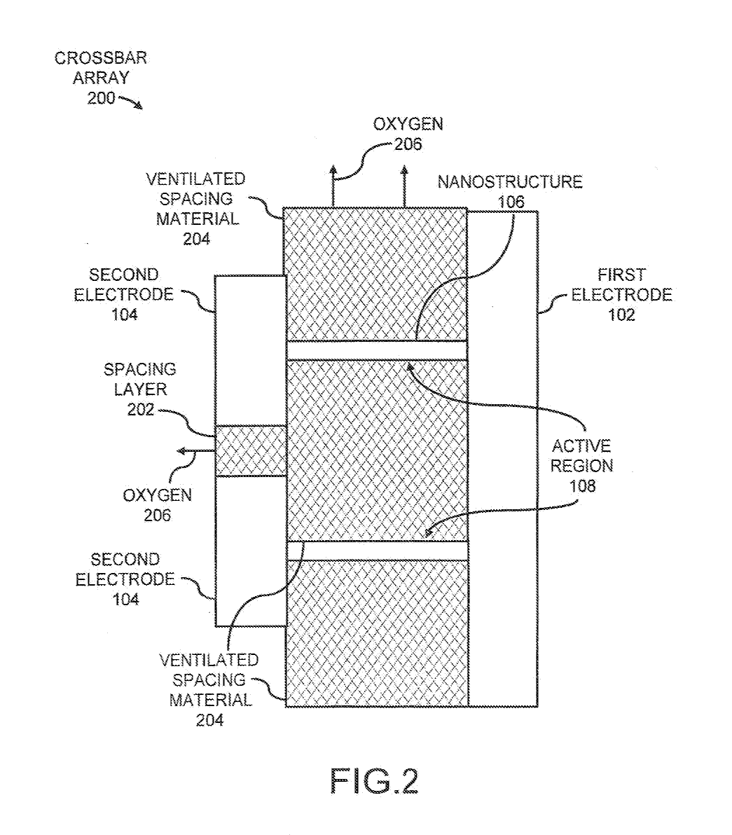

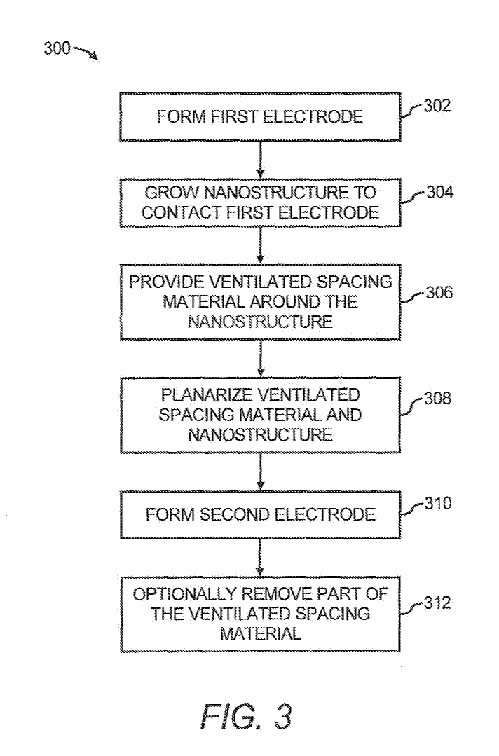

With reference first to FIG. 1A, there is shown a perspective view of a portion of a memristor 100, according to an embodiment. It should be understood that the memristor 100 depicted in FIG. 1A may include additional components and that some of the components described herein may be removed and/or modified without departing from a scope of the memristor 100. It should also be understood that the components depicted in FIG. 1A are not drawn to scale and thus, the components may have different relative sizes with respect to each other than as shown therein. Thus, for instance, the nanostructure 106 may be exponentially smaller than the first and second electrodes 102 and 104 as compared with relative sizes shown in FIG. 1A.

As depicted in FIG. 1A, the memristor 100 includes a first electrode 102, a second electrode 104, and a nanostructure 106 connecting the first electrode 102 to the second electrode 104. In addition, the first electrode 102 is depicted as being in a crossed arrangement with the second electrode 104. The location where the first electrode 102 crosses the second electrode 104 and where the nanostructure 106 is located is considered as a junction or an active region 108 of the memristor 100. The active region 108 may be considered to be the area that becomes conductive during an electroforming process, as described in greater detail herein below. One or both of the first electrode 102 and the second electrode 104 may be formed of metal or semiconductor materials, to enable electricity to be conducted through the first electrode 102 and the second electrode 104. By way of particular example, both the first electrode 102 and the second electrode 104 are formed of platinum.

According to an embodiment, the nanostructure 106 forms the active region 108 of the memristor 100 because the nanostructure 106 is composed of a material that is switched between a generally insulating state and a generally conductive state by migration of oxygen vacancies. The migration of oxygen vacancies in the nanostructure 106 may occur, for instance, through the bias of a voltage applied through the nanostructure 106 across the first electrode 102 and the second electrode 104. In this regard, the nanostructure 106 is composed of a switching material, which is generally electrically insulative and configured to a have an electrically conductive channel formed into the material by a localized field-driven atomic modification. In another embodiment, the nanostructure 106 is composed of a material formed of a molecule having a switchable segment or moiety that is relatively energetically stable in two different states.

The switching material may include any suitable material known to exhibit the above-described properties. By way of particular example the nanostructure 106 is composed of titanium dioxide (TiO₂) or other oxide species, such as nickel oxide or zinc oxide, etc. The nanostructure 106 may also include one or more dopants designed to increase one or more desired properties in the nanostructure 106. For instance, the oxygen content along the length of the nanostructure 106 may intentionally be varied during its growth. In a further example, the nanostructure 106 may be formed of a plurality of different materials, such as, Ti, Ni, Pt, etc. In this example, the nanostructure 106 may be grown under varying conditions along its length to incorporate the different materials.

With reference now to FIG. 1B there is shown an enlarged, cross-sectional front view of the memristor 100 depicted in FIG. 1A, according to an embodiment. It should be understood that the memristor 100 depicted in FIG. 1B may include additional components and that some of the components described herein may be removed and/or modified without departing from a scope of the memristor 100. It should also be understood that the components depicted in FIG. 1B are not drawn to scale and thus, the components may have different relative sizes with respect to each other than as shown therein.

The nanostructure 106 is depicted as having an elongated shape. Although not explicitly shown in FIG. 1B, the nanostructure 106 may have a circular, hexagonal, or other cross-sectional shape. Moreover, although the nanostructure 106 has been depicted as extending perpendicularly between both the first electrode 102 and the second electrode 104, it should be understood that the nanostructure 106 may have other angles with respect to either or both of the first electrode 102 and the second electrode 104. The angular relationship between the nanostructure 106 and the first and second electrodes 102 and 104 has thus been depicted for illustrative purposes only and should not be construed as limiting the memristor 100 to the relationship depicted in FIG. 1B.

In any regard, the nanostructure 106 includes a length 110 that is substantially longer than a thickness 112 of the nanostructure 106. The length 110 of the nanostructure 106 is defined as the distance from one end of the nanostructure 106 to the other end of the nanostructure 106, which is depicted as being substantially perpendicular to the directions that the first electrode 102 and the second electrode 104 extend. The thickness 112 of the nanostructure 106 may be defined as following a dimension that is substantially perpendicular to the length 110 of the nanostructure 106. Thus, the length 110 of the nanostructure 106 is nearly equivalent to the distance between the first electrode 102 and the second electrode 104 at the junction 108 where the nanostructure 106 is positioned in instances where the nanostructure 106 is nearly perpendicular to both the first electrode 102 and the second electrode 104. In instances where the nanostructure 106 is not nearly perpendicular to both the first electrode 102 and the second electrode 104, the length 110 of the nanostructure is larger than the distance between the first electrode 102 and the second electrode 104.

The nanostructure 106 may comprise one or more defects, such as, surface deformations, bends, etc., along the length of the nanostructure 106. In addition, although the nanostructure 106 has been depicted as having a consistent thickness 112 throughout its length 110, it should be understood that the thickness of the nanostructure 106 may vary along its length 110. For instance, the contact points 114 where the nanostructure 106 is respectively connected to the first electrode 102 and the second electrode 104 may be wider than the section of the nanostructure 106 between the contact points 114.

In any regard, the length 110 is generally much longer than the thickness 112 of the nanostructure 106, and thus, the aspect ratio (length/thickness) is very high. In one regard, fabrication of the nanostructure 106 to have the very high aspect ratio generally enables an electrical conduction path to form between the first and second electrodes 102 and 104 around substantially the entire thickness of the nanostructure 106. As such, the nanostructure 106 generally enables the location of the active region 108 to be easily identifiable between the first and second electrodes 102 and 104.

The nanostructure 106 may have a thickness 112 that is sufficiently small to reliably form a single conduction channel. By way of particular example, the thickness 112 is substantially equal to filaments (electrical conduction channels) formed in the switching material of conventional memristors, which is typically between around 5 nm-10 nm. The length 110 of the nanostructure 106 may range from anywhere between a few tens of nanometers to a few micrometers. In any regard, through control over the thickness 112 of the nanostructure 106, there is a relatively high degree of certainty in the threshold voltage required to make the nanostructure 106 change from a generally nonconductive state to a generally conductive state, and vice versa. In addition, the control of the thickness 112 also enables a relatively high degree of certainty in controlling the timing of the change under application of the threshold voltage.

The active region 108 formed of the nanostructure 106 differs from active regions formed in conventional memristors because the conventional active regions are typically formed in a portion of a relatively wide, flat layer of switching material positioned between pairs of crossed electrodes. In other words, the aspect ratio (length/thickness) of the conventional switching material layer is very low. As such, there is a relatively large area between the pairs of crossed electrodes where the active regions may form in conventional memristors. There is thus a relatively high degree of uncertainty in the location and timing of formations of filaments forming the active regions because the filament formation depends on local variation in the metal oxide (switching layer) and fluctuation in the electrical field, as well as other factors, such as, the size and shape of the switching layer. The memristor 100 of the present invention enables this uncertainty in the location and timing of formation of the active region 108 to substantially be removed because the active region 108 is formed of the nanostructure 106.

In addition, the relatively wide, flat configuration of the conventional switching material often provides little or no escape for the oxygen release in the switching material that occurs when the switching material is made electrically conductive through migration of oxygen vacancies through the switching material. Because the oxygen cannot escape, the oxygen often forms bubbles in various areas of the conventional memristors, which has been known to damage the switching material, the electrodes, or both. For instance, bubbles may form at an interface between one of the electrodes and the switching material, which often decreases the performance of the conventional memristors.

In contrast, because the active region 108 of memristor 100 disclosed herein is composed of the nanostructure 106, which is substantially open to the atmosphere, the oxygen released from the nanostructure 106 during electroforming is able to dissipate into the atmosphere. In addition, a large portion of the released oxygen is dissipated by virtue of the relatively large surface area of the nanostructure 106 that is in contact with the atmosphere. One result is that the memristor 100 is also capable of being affected by changes in the atmosphere, such as, temperature, humidity, etc., and lighting conditions and may thus be employed as a sensor configured to detect changes in these or other conditions. By way of particular example, the memristor 100 may be employed in applications where a high level of sensitivity to changes in the surrounding atmosphere is needed. As another example, the memristor 100 may be employed in applications where sensitivity to lighting conditions is needed.

Although the nanostructure 106 has until now been described as being open to the atmosphere, in other embodiments, a ventilated spacing material 204, depicted in FIG. 2, may be placed around the nanostructure 106 to support the nanostructure 106 and/or to maintain separation between the first electrode 102 and the second electrode 104. The ventilated spacing material 204 is discussed in greater detail herein below with respect to FIG. 2.

The memristor 100 depicted in FIGS. 1A and 1B may be built at the micro- or nano-scale and used as a component in a wide variety of electronic circuits. The memristor 100 may be used as the basis for memories, switches and logic circuits, and for switching functions. When used as a basis for memories, the memristor 100 may be used to store a bit of information, 1 or 0. When used as a switch, the memristor 100 may either be a closed or open switch in a cross-point memory. When used as a logic circuit, the memristor 100 may be employed to represent bits in a Field Programmable Gate Array, or as the basis for a wired-logic Programmable Logic Array. The memristors 100 disclosed herein are also configured to find uses in a wide variety of other applications.

With reference now to FIG. 1C, there is shown a crossbar array 120 employing a plurality of the memristors 100 shown in FIGS. 1A and 1B, according to an embodiment. It should be understood that the crossbar array 120 depicted in FIG. 1C may include additional components and that some of the components described herein may be removed and/or modified without departing from a scope of the crossbar array 120.

As shown in FIG. 1C, a first layer 112 of approximately parallel first electrodes 102 is overlain by a second layer 114 of approximately parallel second electrodes 104. The second layer 114 is roughly perpendicular, in orientation, to the first electrodes 102 of the first layer 112, although the orientation angle between the layers may vary. The two layers 112, 114 form a lattice, or crossbar, with each second electrode 104 of the second layer 114 overlying all of the first electrodes 102 of the first layer 112 and coming into close contact with each first electrode 102 of the first layer 112 at respective junctions 106, which represent the closest contact between two of the first and second electrodes 102 and 104. The crossbar array 120 depicted in FIG. 1B may be fabricated from micron-, submicron or nanoscale-electrodes 102, 104, depending on the application.

Although the first electrodes 102 and second electrodes 104 depicted in FIGS. 1A, 1B and 1C are shown with square or rectangular cross-sections, the second electrodes 104 may have circular, hexagonal, or more complex cross-sections, such as, triangular cross-sections. The wires may also have many different widths or diameters and aspect ratios or eccentricities. The term “nanowire crossbar” may refer to crossbars having one or more layers of sub-microscale electrodes, microscale electrodes or electrodes with larger dimensions, in addition to nanowires.

Although not explicitly shown, some or all of the junctions or active regions 108 between the first electrodes 102 and the second electrodes 104 include the nanostructures 106 discussed above with respect to FIGS. 1A and 1B. In addition, although the nanostructures in the crossbar array 120 have been depicted as vertically connecting the electrodes 102 and 104 in the crossbar array 120, they may also horizontally connect neighboring electrodes within the same layer 102 or 104 without departing from a scope of the crossbar array 120.

An example of a junction 200 composed of neighboring electrodes connected by horizontal nanostructures, also having suitable spacing material in the remaining areas, is depicted in FIG. 2.

FIG. 2, more particularly, shows a side, cross-sectional view of a is portion of a crossbar array 200, according to an embodiment. It should be understood that the crossbar array 200 depicted in FIG. 2 may include additional components and that some of the components described herein may be removed and/or modified without departing from a scope of the crossbar array 200. It should also be understood that the components depicted in FIG. 2 are not drawn to scale and thus, the components may have different relative sizes with respect to each other than as shown therein.

The crossbar array 200 is depicted as including a first electrode 102 and two second electrodes 104. The two second electrodes 104 are depicted as being spaced apart from each other by a spacing layer 202. The spacing layer 202 is formed of a material, such as, a dielectric or an insulating material, that substantially prevents conduction of electricity between the two second electrodes 104 and has sufficient rigidity to maintain a desired level of separation between the two second electrodes 104. In addition, the spacing layer 102 may comprise a porous or other suitably configured material that enables oxygen exchange through the material, as denoted by the arrow 206.

Also depicted in FIG. 2 are respective nanostructures 106 extending between the first electrode 102 and the second electrodes 104. Positioned between and around the respective nanostructures 106 is ventilated spacing material 204. According to an embodiment, the ventilated spacing material 204 surrounds each of the nanostructures 106. The ventilated spacing material 204 is formed of a material, such as a dielectric or an insulating material, that substantially prevents conduction of electricity between the nanostructures 106 and has sufficient rigidity to maintain a desired level of separation between the nanostructures 106. In addition, the ventilated spacing material 204 is formed to enable sufficient amounts of oxygen 206 to pass therethrough to substantially prevent formation of bubbles in the crossbar array 200. By way of particular example, the ventilated spacing material 204 is formed to have sufficient oxygen exchange capabilities such that at high biasing, when oxygen is released from the metal oxide of the nanostructures 106, the oxygen passes through the ventilated spacing material 204 into a surrounding atmosphere without distorting the metal oxide of the nanostructure 106, the ventilated spacing material 204, or the electrodes 102, 104.

Turning now to FIG. 3, there is shown a flow diagram of a method 300 of fabricating a memristor 100 having an active region 108 formed of a nanostructure 106, according to an embodiment. It should be understood that the method 300 of fabricating the memristor 100 depicted in FIG. 3 may include additional steps and that some of the steps described herein may be removed and/or modified without departing from a scope of the method 300 of fabricating the memristor 100.

At step 302, a first electrode 102 is formed through any suitable formation process, such as, chemical vapor deposition, sputtering, etching, lithography, etc. At step 304, a nanostructure 106 composed of a switching oxide material is grown, such that, a bottom end of the nanostructure 106 is in contact with the first electrode 102. The means of growing the nanostructure 106 may include metal-catalyzed growth from vapor, liquid, or solid-phase precursors, growth from a chemical solution, or rapid deposition of material vaporized from a solid source.

At step 306, a ventilated spacing material 204 composed of a suitable dielectric material is provided in spaces around the nanostructure 106. At step 308, top surfaces of the ventilated spacing material 204 and the nanostructure 106 are planarized, for instance, by chemical-mechanical polishing to expose a top end of the nanostructure 106. In addition, at step 310, a second electrode 104 is formed on the planarized surface to thereby cause the top end of the nanostructure 106 to contact the second electrode 104.

As an optional step 312, part of the ventilated spacing material 204 may be removed to provide additional ventilation to the nanostructure 106.

According to another embodiment, the ventilated spacing material 204 may be formed with an opening that extends through its length configured to receive material for the nanostructure 106 to be fabricated. According a further example, instead of the ventilated spacing material 204, another supporting material may be positioned adjacent to the first electrode 102 to provide a surface upon which the nanostructure 106 is to be fabricated. In this example, the supporting material may be removed after the nanostructure 106 has been fabricated. The ventilated spacing material 204 may thus be optional in the method 300.

What has been described and illustrated herein is an embodiment along with some of its variations. The terms, descriptions and figures used herein are set forth by way of illustration only and are not meant as limitations. Those skilled in the art will recognize that many variations are possible within the spirit and scope of the subject matter, which is intended to be defined by the following claims—and their equivalents—in which all terms are meant in their broadest reasonable sense unless otherwise indicated.

What is claimed is:

1. A memristor having an active region, said memristor comprising:
a first electrode;
a second electrode; and
a nanostructure connecting said first electrode with said second electrode, said nanostructure comprising a generally electrically insulating material configured to have an electrically conductive channel formed in the material, wherein the nanostructure forms the active region and has a length and a thickness, wherein the length is substantially equivalent to a distance extending from the first electrode to the second electrode along the nanostructure and the thickness is a distance across said nanostructure substantially perpendicular to the length of the nanostructure, and wherein the length of the nanostructure is substantially greater than the thickness of the nanostructure.

2. The memristor of claim 1, wherein the nanostructure comprises at least one nanowire.

3. The memristor of claim 1, wherein the nanostructure has a total surface area and wherein the nanostructure has direct contact with the surrounding atmosphere along a substantial part of the total surface area of the nanostructure.

4. The memristor of claim 1, further comprising:
a spacing material positioned between the first electrode and the second electrode, wherein the spacing material is positioned around the nanostructure.

5. The memristor of claim 4, wherein the spacing material comprises a material from the group consisting of a dielectric and an insulating material.

6. The memristor of claim 4, wherein the spacing material comprises a ventilated material.

7. The memristor of claim 1, wherein the thickness of the nanostructure is sufficiently small to reliably conduct a single electrical conduction channel.

8. The memristor of claim 1, wherein the nanostructure comprises a metal oxide.

9. The memristor of claim 1, wherein the nanostructure comprises a hybrid composition of a plurality of different metals.

10. The memristor of claim 1, wherein the nanostructure comprises different amounts of oxygen content along the length of the nanostructure.

11. A crossbar array composed of a plurality of memristors of claim 1, said crossbar array having respective active regions, said crossbar array comprising:
a plurality of the first electrodes positioned approximately parallel with respect to each other;
a plurality of the second electrodes positioned approximately parallel with respect to each other and approximately perpendicularly with the plurality of first electrodes; and
a plurality of the nanostructures connecting the plurality of first electrodes with said plurality of second electrodes along junctions of the first electrodes and the second electrodes.

12. The crossbar array of claim 11, wherein the plurality of nanostructures each comprises at least one nanowire.

13. The crossbar array of claim 11, further comprising;
a ventilated spacing material positioned between the first electrode and the second electrode, wherein the ventilated dielectric material is positioned around the plurality of nanostructures, and wherein the ventilated spacing material comprises one of a dielectric and an insulating material.

14. A method for fabricating the memristor of claim 1, said method comprising:
forming the first electrode;
growing the nanostructure to have a bottom end of the nanostructure in contact with the first electrode;
providing ventilated spacing material around the nanostructure;
planarizing top surfaces of the ventilated spacing material and the nanostructure; and
forming the second electrode on the planarized top surfaces to cause the second electrode to contact a top end of the nanostructure.

15. The method of claim 14, further comprising:
removing at least a portion of the ventilated spacing material.
